(19) United States
(12) Patent Application Publication
(10) Pub. No.: US 2004/0125964 A1
(43) Pub. Date: Jul. 1, 2004

(54) In-Line Audio Signal Control Apparatus

(75) Inventors: James D. Graham, Deerfield, IL (US); Lionel A. Watson, Deerfield, IL (US)

Correspondence Address: BABCOCK IP LLC, 24154 LAKESIDE DRIVE, LAKE ZURICH, IL, 60047, US

(73) Assignee: Mr. James D. Graham, Deerfield, IL (US)

(21) Appl. No.: 10/248,262

(22) Filed: Dec. 31, 2002

(51) Int. Cl. H04R 1/10; H03G 3/00

(52) U.S. Cl. 381/74; 381/104

(57) ABSTRACT

A high-frequency enhancing, asymmetric audio throughput apparatus for matching a stereo audio signal to a user's specific hearing impaired audiometric profile. Volume controls and or graphic equalizer circuits may be dedicated to each channel to enable tuning of channel specific audio output levels and frequency response. A monaural/stereo selector switch may be used to select between stereo and monaural audio throughput. A balance control may provide further ease of adjustment for the asymmetrically impaired. An attenuation circuit may attenuate the audio signal if it exceeds a desired signal level, preventing damaging signal levels from reaching the user. The apparatus may be located in a housing wearable by the user. The housing may be integrated into a headphone cord or configured with input and output jacks for placement between a portable stereo audio source and a user's headphones.

### BACKGROUND OF INVENTION

1. Field of the Invention

The invention relates to stereo acoustic apparatus. More specifically, the invention relates to a portable volume and frequency equalizing apparatus insertable in-line with existing audio and telephone equipment to enable stereo listening by individuals with high frequency hearing loss in one or both ears improving comprehension of speech, lyrics, and musical melodies.

2. Description of Related Art

A significant portion of the population has untreated hearing loss with a large fraction of those individuals having unequal levels of hearing degradation/loss in each ear. Hearing degradation/loss may be linear across the customary frequency range of 20-20,000 Hertz or it may be limited to specific frequency ranges. Where hearing loss is not evenly spread across the customary frequency range, it tends to be concentrated at higher frequencies.

High frequency hearing degradation/loss makes it difficult to comprehend verbal content whether spoken or sung—especially by children, women and older men whose vocal output tends to be at a higher frequency. Economic, social and psychological factors lead only a small percentage of those tested and determined to have hearing loss treatable by traditional hearing aids to actually purchase them, leaving a very large number in need of other types of assistive devices. In addition, a significant segment may have degraded vocal recognition as a result of high frequency hearing degradation but otherwise have functional hearing for everyday activities, leading to a perception that hearing aids are unnecessary.

The common use of a single low frequency “sub-woofer” speaker teamed with channel separated high frequency speakers in surround sound stereo audio systems, demonstrates the importance of high frequencies in stereo perception. When high frequency or asymmetric hearing loss becomes significant, the ability to hear in stereo becomes impaired limiting the individual's ability to perceive/enjoy stereo signals/music. For example, an otherwise hearing capable individual may have degraded high frequency hearing ability in one or both ears which then inhibits lyric comprehension of stereo music featuring, for example, channel-separated female and or child performers.

A further class of individuals may have no hearing at all in one ear and are limited by the design of common consumer electronics products, for example portable audio devices, to hearing only one channel of a stereo audio source.

A large number of portable stereo audio devices, for example radio, tape, CD, MP3, portable computers and or DVD players, utilize stereo headphones as do some computer and telephone audio headsets. Because of cost and size considerations, common consumer versions of these portable devices do not include volume, balance, and or frequency equalization functionality that is independently configurable for each audio channel and or ear. Also, the consumer portable stereo equipment market favors stereo headphones with minimal size, weight and cost of manufacture. Similar limitations exist with public multi-user systems, for example music store sampling kiosks, theater, health club or airplane audio systems that individuals connect to via headphones.

Previous portable in-line stereo signal level control devices have been limited to a single simultaneous volume control of both channels. Hearing aid apparatus available through audiologists are generally not configured for in-line use and may be prohibitively expensive, placing them out of reach of the marginally hearing impaired or those not ready for hearing aids who merely seek to regain the full frequency range stereo audio experience, or hear better when using a telephone, computer headset or speakers.

Therefore, it is an object of the invention to provide an apparatus that overcomes deficiencies in the prior art.

### BRIEF DESCRIPTION OF DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 shows a perspective view of a person using one embodiment of the invention.

FIG. 2 shows a block diagram of an asymmetric control embodiment of the invention.

FIG. 3 shows a block diagram of a common channel control embodiment of the invention.

FIG. 4 shows a block diagram of an asymmetric control embodiment of the invention including attenuation circuitry.

FIG. 5 shows a block diagram of a common channel control embodiment of the invention including attenuation circuitry.

FIG. 6 shows a detailed circuit diagram of an asymmetric control embodiment of the invention.

### DETAILED DESCRIPTION

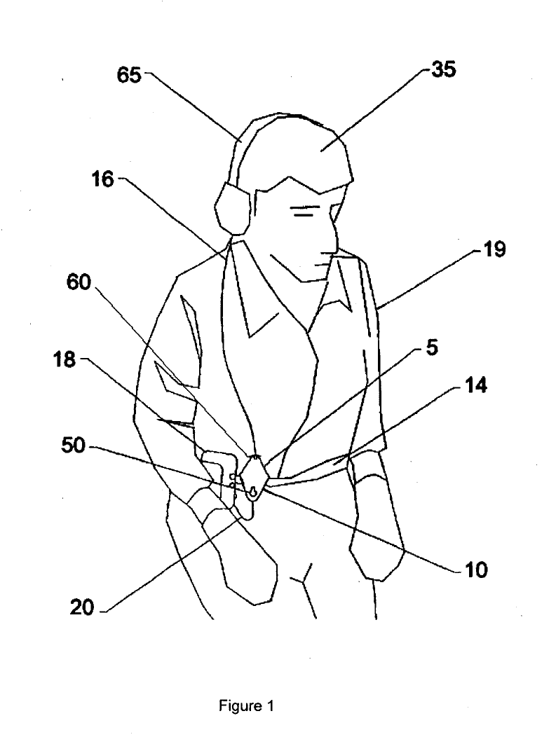

As shown in FIG. 1, the various embodiments of the apparatus 5 may be compactly formed in a housing 10 configured to attach to a user's belt 14. Alternatively, the housing 10 may for example, hang freely from the headphone cord 16 or be mountable on the audio generating device 18, the user's arm 19 or hat. The housing 10 and any clip, attachment, mounting or other means for attachment may be formed from, for example, metal and or injection molded plastic.

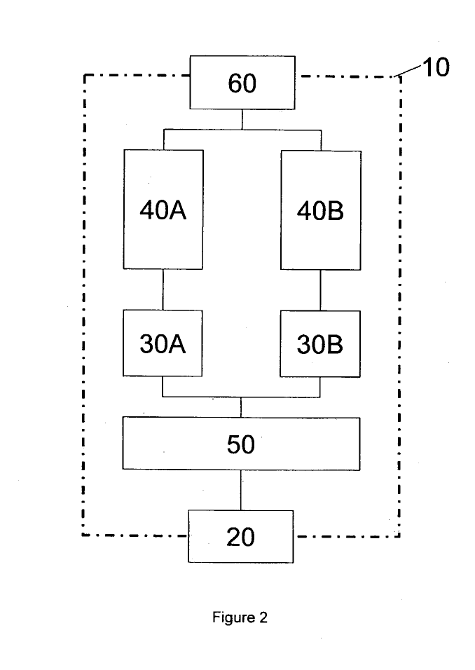

An example of an asymmetric channel control embodiment is shown in FIG. 2. An input plug 20 couples the apparatus to the stereo audio source jack. The input plug 20 may include a length of electrical cable to which the actual plug is attached; the length of the cable may be selected to reach the anticipated location of the audio signal source from the housing 10. The plug may be, for example, a standard three conductor ⅛″ or ¼″ stereo phone plug, telephone handset plug (such as RJ11) or a proprietary plug. Alternatively, a jack of the desired type may be used, for connection in-line with existing cabling/plugs.

Volume level controls 30A and 30B are provided for independent control of each channel. The volume level controls 30A and 30B may be for example, potentiometers, trimmers or rheostats in, for example, pot or slider configuration. Volume controls 30A and 30B (for channel A and channel B respectively) may be integrated into a single dual channel balance control, for example a stacked potentiometer or rheostat with the channels acting inversely of each other over the potentiometer or rheostat's direction of travel. In addition to a balance/volume function 30A and 30B, a second master volume control 30 A/B, may be included as a master audio level control local to the apparatus 5.

Graphic equalizers 40A and 40B (channel A and channel B respectively) may be added to separately tune the individual frequency response of each channel. The graphic equalizer circuitry may include a plurality of RC filter circuits each with a variable resistance and or capacitance for amplifying or attenuating a specific frequency band. Alternatively, digital graphic equalizer circuits may be used.

Specific graphic equalizer circuitry is well known to one skilled in the art. The number of frequency band controls used and the type of circuits used is a design tradeoff between cost and the desired specificity of the frequency equalization control functionality desired.

The external user controls of the graphic equalizers 40A and 40B may be for example, a plurality of sliders for each channel, one for each frequency band or a plurality of Dual-Inline-Package (DIP) switches for setting a fixed frequency response for the audiometric profile of each ear of an individual intended user.

A selector switch 50 selects either monaural or stereo audio throughput. The selector switch 50 may be used for setting an initial volume balance between the channels in light of a broadband asymmetric hearing loss, or it may be kept permanently in the monaural position when used by a person with total hearing loss in one ear only. The selector switch 50 may be, for example, a toggle, rocker, pushbutton or slider switch.

An output jack 60 couples the volume and or frequency adjusted/equalized audio signal to the users headphones 65. The output jack 60 may be, for example, a standard three-conductor ⅛″ or ¼″ stereo phone jack, a telephone handset jack to receive an RJ11 plug, or a proprietary jack. It may be integrated into the housing of the apparatus or may include a length of electrical cable to which the actual jack is attached.

In operation, the apparatus 5 is inserted in-line with the audio generating device 18 and, for example, the users headphones 65 via input plug 20 and output jack 60. The user 35 sets the selector switch 50 to monaural audio throughput and adjusts the volume level controls 30A and or 30B for either channel until equal volume is perceived in each channel. After adjustment, the selector switch 10 is set to stereo and the stereo effect should then be centered at the user 35. Further adjustments may then be made for specific frequency band response by adjusting the graphic equalizer controls 40A and 40B of each channel. If unimpaired frequency bands are attenuated to allow better perception of an impaired frequency band, the volume controls 30A and or 30B may be rebalanced as previously described.

Used with a monophonic audio input, for example a telephone, the apparatus 5 may be used to provide a hearing impaired individual with audio tuned to the users specific audiometric profile, the audio signal optimized for specific characteristics of each ear, thereby boosting overall audio/speech recognition.

In alternative embodiments, the apparatus may be integrated/permanently attached to a headphone cord 16 or other audio output device, eliminating the need for the output jack 60. Also, the external controls and housing may be configured for moisture and vibration resistance using sealing gaskets and or an over cover for the housing. In a minimized size and or manufacturing cost embodiment, the controls may each be provided in a high density DIP format for semi-permanent adjustment specific to an intended users audiometric profile and then sealing within the housing 10.

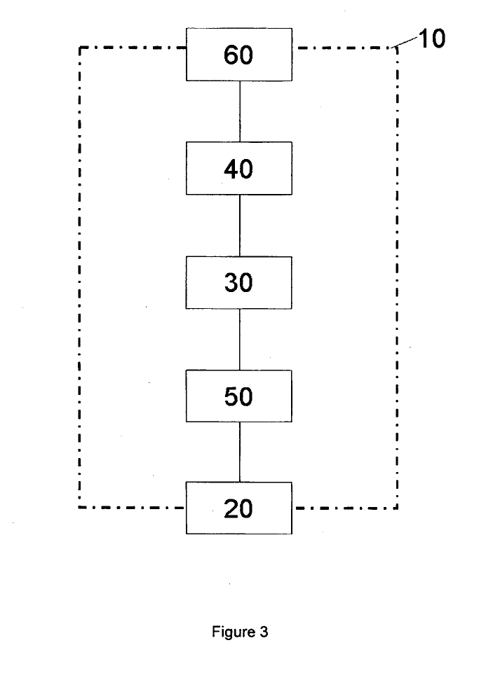

As shown in FIG. 3, the invention may be simplified if asymmetric channel control is not required, for example where an individual's hearing loss is not asymmetric or the signal is monophonic, for example a telephone signal. Common components are similarly labeled without dual channel A/B designations, their effect on the signal being common to each channel. Using this embodiment, size and cost may be minimized but the ability to adapt for an individual's specific frequency range degradation is maintained.

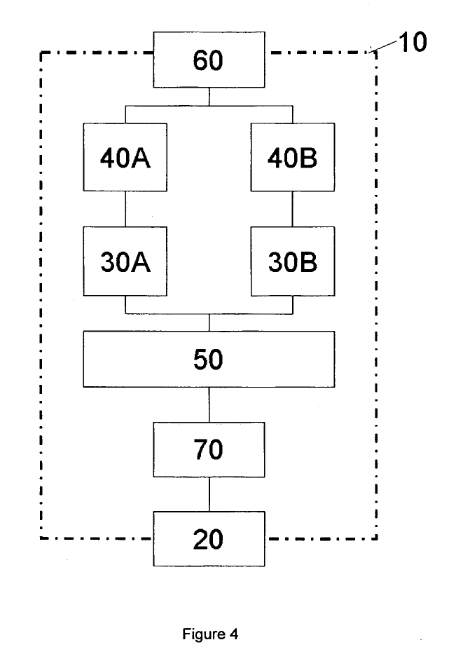

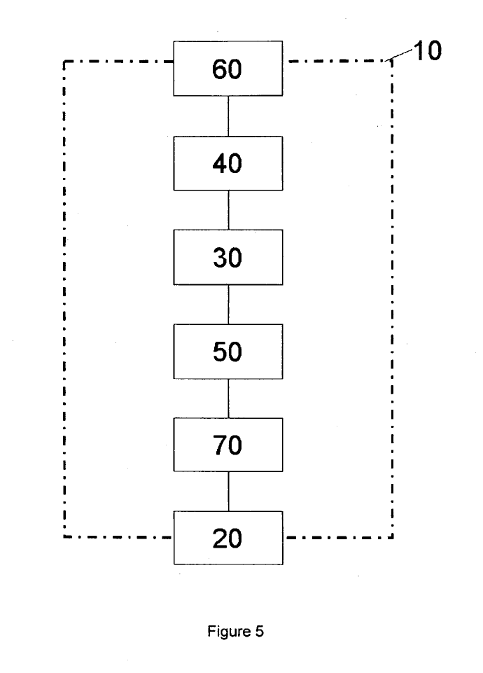

Other embodiments of the invention, as shown for example in FIGS. 4 and 5, may include signal level attenuation circuitry 70. An example of attenuation circuitry is disclosed in U.S. Pat. No. 6,442,279 issued to Preves et al. on Aug. 27, 2002 and hereby incorporated by reference in its entirety. Contained in the attenuation circuitry 70, a monitoring circuit monitors the incoming signal level and attenuates the signal if it exceeds a selectable maximum level, thereby protecting the user from steady state and or sudden signal level increases that may result in a damaging volume level being transmitted to the user, contributing to further hearing degradation.

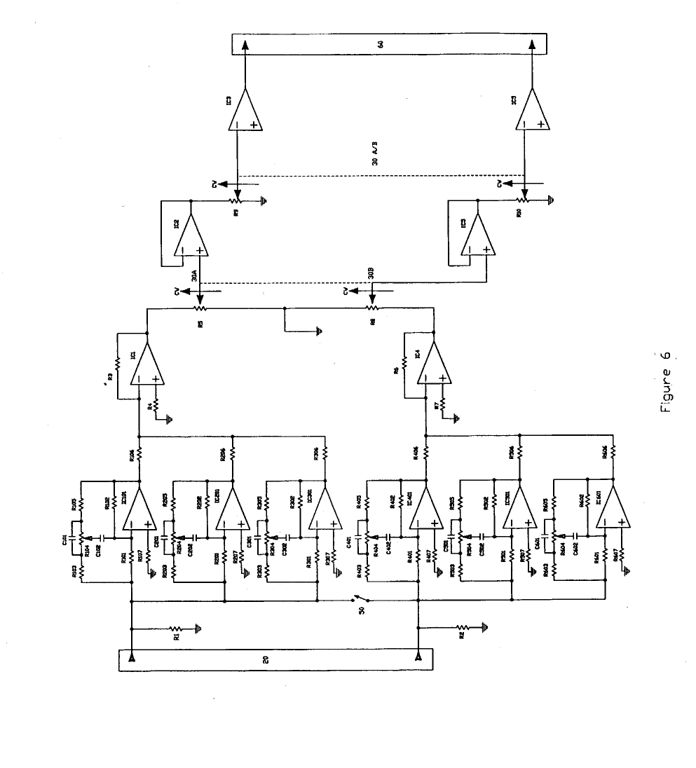

A specific example of electrical circuitry for one embodiment of the invention, is shown in FIG. 6 (power supply circuits omitted for clarity). The graphic equalizers (40A, 40B of FIGS. 2 or 3) in this embodiment are formed by three sub circuits for each channel, associated components are designated by common ordinals, for example R101, R102, R103, R104, R105, R106, C101, C102 and IC101 together form a variable throughput circuit for a specific frequency band determined by the resistance and capacitance values selected. Adjusting the value of variable resistance R104 varies the throughput of the specific frequency band. Alternatively, a switch, for example a DIP switch, may be used to select between a plurality of different resistances for R104.

More or less than the three sub circuits per channel may be used. Adding additional sub circuits allows the specific frequency band of each sub circuit to be narrowed, increasing the users ability to tune to a desired frequency profile for each channel.

Volume controls 30A and 30B may be configured to operate in common as a balance control between the channels. An additional volume control 30A/B may be an output master volume control usable in addition to any volume control available on the audio source. For maximum economy, separately adjustable volume controls 30A and 30B may be used and the additional volume control 30A/B omitted.

impaired users, especially those with high-frequency and or asymmetric impairment, to use with existing stereo audio sources, headphones, headsets and or speakers to improve speech recognition and the understanding of song lyrics, regain the stereo audio experience, and/or increase perception of impaired frequency bands. The apparatus may be formed in a small portable configuration for in-line use during active listening and or attached in-line between static devices, for example a telephone unit and a headset.

Table of Parts

| | |
|---|---|
| 5 | apparatus |
| 10 | housing |
| 14 | belt |
| 16 | headphone cord |
| 18 | audio generating device |
| 19 | arm |
| 20 | input jack |
| 30 | volume control |
| 30A | volume control (channel A) |
| 30B | volume control (channnel B) |
| 35 | User |
| 40 | graphic equalizer |
| 40A | graphic equalizer (channel A) |
| 40B | graphic equalizer (channel B) |
| 50 | selector switch |
| 60 | output jack |
| 65 | headphones |
| 70 | attenuation circuit |

Where in the foregoing description reference has been made to materials, circuits, ratios, integers or components having known equivalents then such equivalents are herein incorporated as if individually set forth.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus, methods, and illustrative examples shown and described. Accordingly, departures may be made from such details without departure from the spirit or scope of applicant's general inventive concept. Further, it is to be appreciated that improvements and/or modifications may be made thereto without departing from the scope or spirit of the present invention as defined by the following claims.

1. An audio signal control apparatus, comprising:
a first audio channel volume control;
a second audio channel volume control;
a monaural/stereo selector switch;
the first audio channel volume control and the second channel volume control coupled to the monaural/stereo selector switch and mounted in a housing.

2. The apparatus of claim 1, wherein the first audio channel volume control and the second audio channel volume control are integrated into a left-right balance control.

3. The apparatus of claim 1, further including:
a first audio channel graphic equalizer circuit coupled to the first audio channel volume control; and
a second audio channel graphic equalizer circuit coupled to the second audio channel volume control.

4. The apparatus of claim 1, further including:
an input plug coupled to the monaural/stereo selector switch.

5. The apparatus of claim 4, wherein the input plug is at a first end of an electrical cable and a second end of the electrical cable is coupled to the monaural/stereo selector switch.

6. The apparatus of claim 4 wherein the input plug is one of a ⅛″ stereo phone jack, a ¼″ stereo phone jack and an RJ-11 telephone jack.

7. The apparatus of claim 1, further including:
an output jack coupled to the first audio channel volume control and the second audio channel volume control.

8. The apparatus of claim 7, wherein the output jack is one of a ⅛″ stereo phone plug, a ¼″ phone plug and an RJ-11 telephone jack.

9. The apparatus of claim 1, wherein the housing is located inline on an electrical cable coupled to one of a pair of headphones and a plurality of speakers.

10. The apparatus of claim 1, wherein the housing has a means for attachment to a desired mounting point.

11. The apparatus of claim 1, further including a signal level attenuation circuit configured to attenuate a signal level below a desired maximum signal level.

12. The apparatus of claim 11, wherein the signal level attenuation circuit is coupled to the monaural/stereo selector switch.

13. An audio signal control apparatus, comprising:
an input plug,
a volume control;
a graphic equalizer; and
an output jack
the input plug, volume control, graphic equalizer and output jack coupled together and housed in a housing.

14. The apparatus of claim 13, further including a signal level attenuation circuit configured to attenuate a signal level below a selectable maximum signal level.

15. The apparatus of claim 13, wherein the input plug is at a first end of an electrical cable and a second end of the electrical cable is coupled to the volume control.

16. The apparatus of claim 15 wherein the input plug is one of a ⅛″ stereo phone jack, a ¼″ stereo phone jack and an RJ-11 telephone jack.

17. The apparatus of claim 13, further including:
an output jack coupled to the graphic equalizer.

18. The apparatus of claim 13, wherein the housing is located inline on an electrical cable coupled to a pair of headphones.

19. The apparatus of claim 13, wherein the housing has a water resistant seal.

20. A portable audio signal control apparatus, comprising:
a housing with
an audio input and
an audio output;
a first audio channel volume control;
a second audio channel volume control;
a first audio channel graphic equalizer circuit coupled to the first audio channel volume control; and
a second audio channel graphic equalizer circuit coupled to the second audio channel volume control;
the first audio channel volume control, the second audio channel volume control, first audio channel graphic equalizer circuit and second audio channel graphic equalizer circuit coupled between the audio input and the audio output and located within the housing; configurable from outside of the housing.
